(19) United States
(12) Patent Application Publication
(10) Pub. No.: US 2023/0191448 A1
(43) Pub. Date: Jun. 22, 2023

(54) PHOTOCURING DEVICE

(71) Applicant: BEIJING DREAM INK TECHNOLOGIES CO., LTD., Beijing (CN)

(72) Inventors: Shuanghao LU, Beijing (CN); Tao YIN, Beijing (CN); Jinquan ZHANG, Beijing (CN); Yuanhao KANG, Beijing (CN); Haibo WANG, Beijing (CN)

(21) Appl. No.: 17/776,628

(22) PCT Filed: Nov. 23, 2021
(86) PCT No.: PCT/CN2021/132374

§ 371 Date: May 13, 2022

(30) Foreign Application Priority Data
Feb. 2, 2021 (CN) 202110143719.0

(51) Int. Cl. B05D 3/06; H05K 3/00

(52) U.S. Cl. CPC B05D 3/067; H05K 3/0082

(57) ABSTRACT

Provided is a photocuring device (100), including: a base (40); a light source (10) fixed on the base (40); a tray (20) configured to place a substrate (200) to be processed; and a digital mask (30) placed between the light source (10) and the tray (20) and configured to display corresponding light-shielding pattern (31) according to electronic graphics set by a user, so that light emitted by the light source (10) passes through the digital mask (30) to perform photocuring complementary to the light-shielding pattern (31) for the substrate (200) placed on the tray (20). The photocuring device (100) displays the light-shielding pattern (31) corresponding to the electronic graphics through the digital mask (30) according to the user's requirements, so that the light-shielding/light-transmitting of each area on the plane of the digital mask (30) can be satisfied, thereby achieving the patterning light required by the user.

### CROSS-REFERENCE TO RELATED APPLICATIONS

The present application claims priority to Chinese Patent Application No. 2021101437190, filed on Feb. 2, 2021, and entitled with “Photocuring Device”, the content of which is incorporated herein by reference in its entirety.

### TECHNICAL FIELD

The present disclosure relates to the technical field of photo patterning control and, particularly, relates to a photocuring device.

### BACKGROUND

A UV curing machine is a device that uses a UV light source to cure a UV coating, chemical reaction occurs to a photosensitizer in the UV coating to achieve instant drying and curing. The UV photo curing machine, also known as the UV coating device, has a wide range of applications, such as products that require UV coating for flat or three-dimensional workpieces. With the continuous development of photosensitive materials, their application scenarios are also expanding, such as a curing device in integrated circuit (PCB board) production lines, a curing machine for 3D printing, and a curing lamp for manicure.

Although the application of the above-mentioned curing products has become more and more mature, curing machines for 3D printing and curing lamps for manicure and the like perform all-round photocuring on objects to be treated, which cannot meet the requirements of patterned photocuring. The curing device in integrated circuit (PCB board) production lines needs to cooperate with a traditional mask to achieve patterned photocuring. Since the mask needs an addition manufacturing process, the requirements of personalization and fast photo patterning processing cannot be satisfied yet.

### SUMMARY

In view of this, an object of the present disclosure is to propose a photocuring device, which can solve the problem that the related art cannot meet the needs of personalization and fast photo patterning processing.

In some illustrative embodiments, the photocuring device includes: a base; a light source fixed on the base; a tray configured to place a substrate to be processed; and a digital mask placed between the light source and the tray and configured to display corresponding light-shielding pattern according to electronic graphics set by a user so that light emitted by the light source passes through the digital mask to perform photocuring complementary to the light-shielding pattern for the substrate placed on the tray.

In some illustrative embodiments, a distance between the light source and the digital mask is in a range from 10 mm to 500 mm.

In some illustrative embodiments, a distance between the digital mask and the substrate is in a range from 0 mm to 30 mm.

In some illustrative embodiments, the photocuring device further includes: a light shield provided between the light source and the digital mask to prevent light leakage.

In some illustrative embodiments, the photocuring device further includes: a housing. The housing covers the light source, the tray, and the digital mask.

In some illustrative embodiments, the photocuring device further includes: a moving component assembled on the base. The tray is provided on the moving component so that the tray is capable of being drawn out by the moving component to place the substrate or take out the substrate, and the tray is capable of being pushed in by the moving component to align the substrate with the digital mask.

In some illustrative embodiments, the moving component is a tray seat for fixing the tray, and the tray seat is mounted on the base through a slide rail.

In some illustrative embodiments, the photocuring device further includes: an approaching component cooperating with the tray. The approaching component is configured to drive the substrate to approach the digital mask when the tray is pushed in, and drive the substrate to move away from the digital mask when the tray is being drawn out.

In some illustrative embodiments, the digital mask is a digitally controlled light-shielding and light-transmitting display panel.

In some illustrative embodiments, each of pixel points on the digitally controlled light-shielding and light-transmitting display panel is capable of forming a light-shielding pixel point or a light-transmitting pixel point according to the electronic graphics set by the user; the light-shielding pixel points constitute the light-shielding pattern, the light-transmitting pixel points constitute a light-transmitting pattern, and a pattern combined by the light-shielding pattern and the light-transmitting pattern is in consistent with a pattern irradiated on the substrate by the light source.

In some illustrative embodiments, the digital mask is selected from an LCD display panel or an OLED display panel.

In some illustrative embodiments, light emitted by the light source has a wavelength of 350 nm to 460 nm.

In some illustrative embodiments, an optical lens is provided between the light source and the digital mask and configured to convert a direction of the light emitted by the light source as a direction perpendicular to the digital mask.

In some illustrative embodiments, the photocuring device further includes: a heat dissipation component provided on a back plate of the light source.

Compared with the related art, the present disclosure can bring the following advantages.

The photocuring device according to the present disclosure displays the light-shielding pattern corresponding to the electronic graphics through the digital mask according to the user's requirements, so that the light-shielding/light-transmitting of each area on the plane of the digital mask can be satisfied, thereby achieving the patterning light required by the user. In embodiments of the present disclosure, due to the numerical control advantage of the digital mask, the user's diversified optical patterning requirements can be met without manufacturing of the mask, processing efficiency is improved, device requirements are reduced, and manufacturing cost is saved.

### BRIEF DESCRIPTION OF DRAWINGS

FIG. 1 is a structural example I of a photocuring device according to an embodiment of the present disclosure;

FIG. 2 is a structural example II of a photocuring device according to an embodiment of the present disclosure;

FIG. 3 shows a display example of a digital mask according to an embodiment of the present disclosure;

FIG. 4 is a structural example III of a photocuring device according to an embodiment of the present disclosure;

FIG. 5 is a structural example IV of a photocuring device according to an embodiment of the present disclosure;

FIG. 6 is a schematic diagram of the structural example IV with a tray being pulled out according to an embodiment of the present disclosure;

FIG. 7 is a structural example V of a photocuring device according to an embodiment of the present disclosure;

FIG. 8 is a schematic diagram of the structural example V with a tray moving upward according to an embodiment of the present disclosure;

FIG. 9 is a structural example VI of a photocuring device according to an embodiment of the present disclosure;

FIG. 10 is a schematic diagram of the structural example VI with a tray being pushed into according to an embodiment of the present disclosure;

FIG. 11 is a structural schematic diagram of a tray according to an embodiment of the present disclosure;

FIG. 12 is a structural schematic diagram of a tray in a spring-compressed state according to an embodiment of the present disclosure;

FIG. 13 is a structural schematic diagram of a light shield according to an embodiment of the present disclosure;

FIG. 14 is a structural schematic diagram of a housing according to an embodiment of the present disclosure;

FIG. 15 is a structural schematic diagram of an optical lens according to an embodiment of the present disclosure;

FIG. 16 is a structural example VII of a photocuring device according to an embodiment of the present disclosure; and

FIG. 17 is a schematic diagram of the structural example VII with a tray being pulled out according to an embodiment of the present disclosure.

### DESCRIPTION OF EMBODIMENTS

The following description and drawings sufficiently illustrate specific embodiments of the present disclosure to enable those skilled in the art to implement them. Other embodiments may include structural, logical, electrical, procedural or other changes. The examples represent only possible variations. Unless expressly required, individual components and functions are optional and the order of operations may be varied. Portions and features of some embodiments may be included in other embodiments or substituted by portions and features of other embodiments. The scope of embodiments of the present disclosure is defined by the claims, and all available equivalents thereof. These embodiments of the present disclosure may be referred to herein by the term “invention” individually or collectively for convenience only. If more than one invention is actually disclosed, the scope of the present disclosure does not automatically limit the present disclosure to any single invention or inventive concept.

It should be noted that various technical features in embodiments of the present disclosure can be combined with one another if there is no conflict.

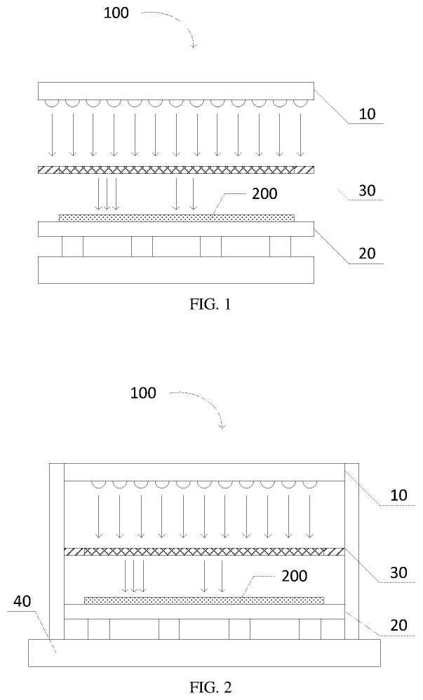

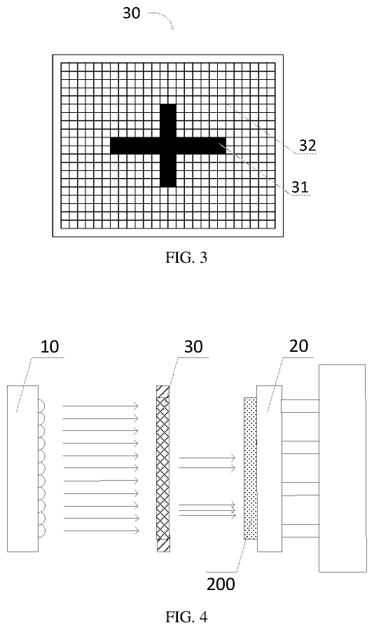

A first aspect of the present disclosure discloses a photocuring device. As shown in FIG. 1 to FIG. 3, FIG. 1 is a structural example I of a photocuring device according to an embodiment of the present disclosure, FIG. 2 is a structural example II of a photocuring device according to an embodiment of the present disclosure, and FIG. 3 is a display example of a digital mask according to an embodiment of the present disclosure. A photocuring device 100 includes: a light source 10, a tray 20, and a digital mask 30 between the light source 10 and the tray 20. The light source 10 is configured to emit light required for photocuring. The tray 20 is configured to place a substrate 200 to be processed. The digital mask 30 is configured to display a corresponding light-shielding pattern 31 according to electronic graphics set by a user, so that the light emitted from the light source 10 penetrates the digital mask 30 to perform photocuring corresponding to the light-shielding pattern 31 on the substrate 200 placed on the tray 20. In some embodiments, the photocuring device further includes: a base 40 for fixing the light source 10, the tray 20 and the digital mask 30.

The digital mask 30 in embodiments of the present disclosure is an electronic display panel, which can control each pixel point on the display panel by a system, and form light-shielding pixel points/transmitting pixel points according to certain control requirements. A combination of these light-shielding pixel points constitutes a light-shielding pattern 31, and a combination of light-transmitting pixel points constitutes a light-transmitting pattern 32 opposite to the light-shielding pattern. The light-shielding pattern 31 and the light-transmitting pattern 32 are combined together to form an entire display surface of the display panel.

The electronic graphics set by the user can be consistent with the light-shielding pattern 31, while the light-transmitting pattern 32 is complementary to the electronic graphics. In other examples, the electronic graphics set by the user can also be consistent with the light-transmitting pattern 32, and the light-shielding pattern 31 is complementary to the electronic graphics. A relationship between the electronic graphics, the light-shielding pattern, and the light-transmitting pattern can be set/designed in software by developers and users.

The electronic display panel in embodiments of the present disclosure may be any digitally controlled light-shielding/transmitting display panel on the market that can meet the above requirements. The display panel is, for example, an LCD display panel, an OLED display panel, and the like. For traditional display panels, the display panel unpowered has black/green screen color, and each pixel point can become light-shielding/transmitting according to display requirements when powered on. For example, a traditional LCD liquid crystal display panel generally includes a first polarizing layer, a first electrode layer, a liquid crystal layer, a second electrode layer, and a second polarizing layer that are stacked in sequence. The first electrode layer and the second electrode layer controls the liquid crystal layer between the first electrode layer and the second electrode layer, so that light transmitting and light-shielding of the corresponding pixel points are performed. The display principle of the LCD display panel is common knowledge and will not be elaborated here. In some embodiments, a display panel suitable for the present disclosure can be obtained by purchasing a display screen on the market and removing a light-emitting backboard and a reflective layer of the display screen.

Regarding the light-shielding and light-transmitting discussed in embodiments of the present disclosure, dark color (opaque) display is adopted to obtain a light-shielding effect, and light color (transparent) display is adopted to obtain a light-transmitting effect.

In addition to the traditional display panels, the transparent (light-transmitting) display panels currently on the market can also meet the light-shielding/light-transmitting requirements of the pixel points in embodiments of the present disclosure, that is, dark color (opaque) display is adopted to obtain a light-shielding effect, and the rest remains transparent.

The photocuring device according to the present disclosure displays the light-shielding pattern corresponding to the electronic graphics through the digital mask according to the user's requirements, so that the light-shielding/light-transmitting of each area on the plane of the digital mask can be satisfied, thereby achieving the patterning light required by the user. In embodiments of the present disclosure, due to the numerical control advantage of the digital mask, the user's diversified optical patterning requirements can be met without mask manufacturing process, the processing efficiency is improved, device requirements are reduced, and manufacturing cost is saved.

In general, the light source 10, the tray 20 (the substrate 200), and the digital mask 30 in embodiments of the present disclosure constitute a vertical structure, and may be placed by stacking in a vertical direction as shown in FIG. 1, or may arranged in a horizontal direction as shown in FIG. 4 or in any other angles relative to one another. In some embodiments, the positions of the light source 10, the tray 20 (the substrate 200) and the digital mask 30 may not completely satisfy the vertical arrangement but still can achieve a certain degree of the technical effect, or may configure additional light steering components, which may increase device cost and device complexity.

In some embodiments, in order to achieve the vertical structure among the light source, the digital mask and the tray (substrate), the photocuring device may include necessary supporting and fixing structures such as supports, brackets, and frames.

In some embodiments, a distance between the light source 10 and the digital mask 30 may range from 10 mm to 500 mm. In some embodiments, the distance between the light source 10 and the digital mask 30 is set to be 100 mm to 250 mm Within this range, the influence of divergent light (light not perpendicular to the digital mask 30) emitted by the light source 10 on photocuring accuracy can be reduced, so that the light accuracy of photocuring device is improved. On the other hand, within this range, it can ensure that the light intensity of the digital mask emitted from the light source, thereby reducing the photocuring time, improving the efficiency of photocuring, and reducing the energy consumption of the device. Moreover, this range is also conducive to miniaturization requirement of the photocuring device, and can avoid the problem of excessively large size of the device caused by an excessively long optical path.

In some embodiments, a distance between the digital mask 30 and the substrate 200 on the tray 20 may range from 0 mm to 30 mm Within this range, the influence of divergent light on light accuracy can be reduced, so that the light penetrating the digital mask 30 irradiates on a target region of the substrate 200 opposite to it as much as possible, rather than on a non-target region of the substrate 200. In some embodiments, the distance between the digital mask 30 and the substrate 200 on the tray 20 can be in a range of 0 mm to 5 mm. On the one hand, it can well reduce the influence of divergent light, and on the other hand, it is easy to implement placement/replacement of the substrate, and facilitate alignment between the substrate and the digital mask, thereby avoiding scratches on the substrate and the digital mask caused by contact friction between the substrate and the digital mask during the alignment.

The distance between the digital mask 30 and the tray 20 can be designed with reference to the above-mentioned distance between the digital mask 30 and the substrate 200, so that the distance between the digital mask and the substrate can satisfy the above requirements.

In some embodiments, the positions among the light source 10, the digital mask 30, and the tray 20 can be adjusted to meet the usage requirements of designers or users.

In some embodiments, the positions of the light source 10, the digital mask 30 and the tray 20 in the photocuring device 100 are fixed after release from factory. In view of a small distance between the digital mask 30 and the tray 20, placing/taking of the substrate 200 on the tray 20 is achieved by a sideslip manner, and the tray 20 can be provided with a corresponding chute according to the size of the substrate, to guide and catch the substrate for aligning and fixing.

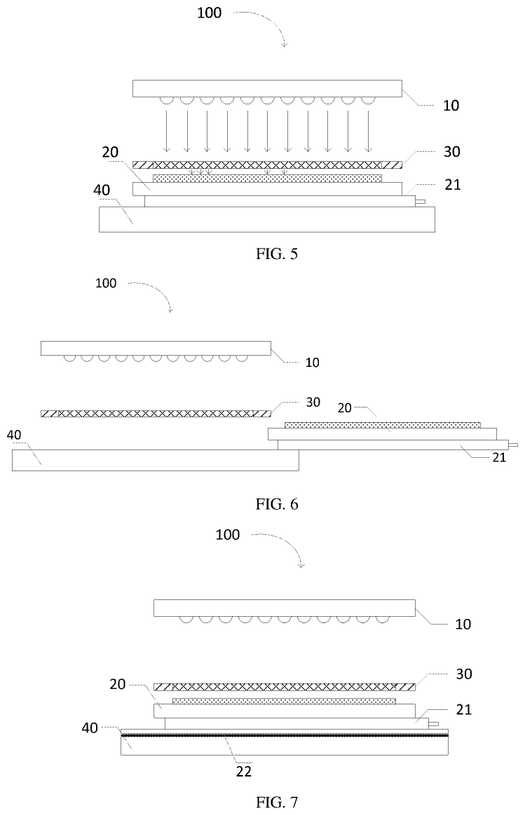

As shown in FIG. 5 and FIG. 6, in some other embodiments, the photocuring device 100 may further include a moving component 21. The moving component 21 is connected to or cooperates with the tray 20 to drive the tray 20 to move into or move out from a position relative to the digital mask 30, so that when the tray 20 is moved out, the user can place/take the substrate, and after the substrate is placed, the tray 20 can be moved in to align the substrate 200 with the digital mask 30. The moving component 21 is not limited to a rotating structure, a sliding rail structure, a telescopic structure and the like.

In some embodiments, the moving component 21 can adopt a tray seat driven by a slide rail. The tray seat is mounted on the base 40 through the slide rail. The tray 20 is assembled on the tray seat. When the tray seat is drawn out through the slide rail, the user can operate the substrate. When the tray seat is fully pushed in, the substrate 200 on the tray 20 can align with the digital mask 30.

Fixing substrate 200 on the tray 20 in the embodiments of the present disclosure is not limited to a clamping platform, catching, clamping, adsorbing, sticking, and the like. In some embodiments, the tray 20 is provided with a positioning post for cooperating with a positioning hole on the substrate. The substrate is sleeved on the positioning post through the positioning hole to achieve positional fixation.

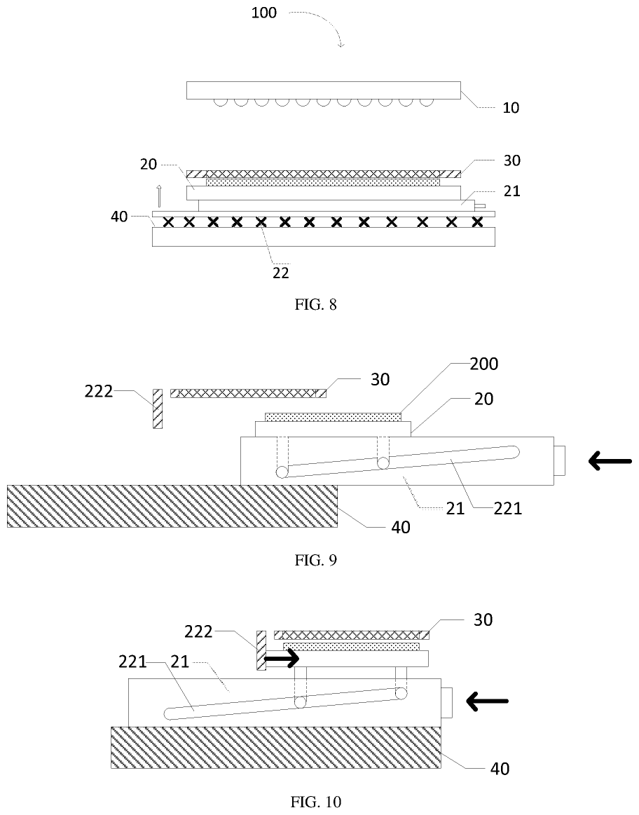

As shown in FIG. 7 to FIG. 8, in some embodiments, the photocuring device 100 may further include an approaching component 22. The approaching component 22 is connected to or cooperates with the tray 20, so that the tray 20 is driven to drive the substrate 200 to approach the digital mask 30 when/after the substrate 200 on the tray 20 is aligned with the digital mask 30, thereby reducing the distance between the substrate 200 and the digital mask 30, or even making the substrate 200 directly attached on the digital mask 30 to achieve the effect of zero distance between the digital mask 30 and the substrate 200. In addition, the design is beneficial to avoid friction between the substrate 200 and the digital mask 30, and reduce the probability of scratches on the substrate 200 and the digital mask 30. The approaching component 22 is not limited to a lift platform, a spring, a slide rail, a clamping platform, and the like.

As shown in FIG. 9 to FIG. 10, in some embodiments, the approaching component 22 may include: an inclining chute 221 provided on the tray seat. The inclining chute 221 has a guiding direction same as the moving direction of the tray seat, and inclines downward in a pushing-in direction of the tray seat. The tray 20 is assembled on the tray seat through the inclining chute 221 so that the tray 20 can move on the tray seat along the inclining chute 221. Since the inclining chute 221 inclines downward in the pushing-in direction of the tray seat, when the tray 20 moves in the pushing-in direction through the inclining chute 221, its position relative to the digital mask 30 has an increased vertical relative distance. On the contrary, when the tray 20 moves in the pulling-out direction through the inclining chute 221, its position relative to the digital mask 30 has a reduced vertical relative distance. Under normal circumstances, the tray 20 will tend to move, due to its own gravity, to a lower end of the inclining chute 221, and in the absence of external force, the tray 20 will always be at the lower end of the inclining chute 221. The approaching component 22 further includes a positioning baffle 222. The positioning baffle 222 is provided on a moving path of the tray 20 to block the movement of the tray 20, and cooperates with the tray seat and the inclining chute 221, aligning the substrate 200 on the tray 20 with the digital mask 30 and approaching to the digital mask 30. In this embodiment, when the tray seat is pushed in from outside to inside, the tray 20 is located at the lower end of the inclining chute 221. During the tray seat is gradually pushed in, the tray 20 is in contact with the positioning baffle 222, and starts to move backwards relative to the inclining chute 221 due to the blocking of the positioning baffle plate 222, so that the tray 20 gradually climbs along the inclining chute 221, thereby making the substrate 200 on the tray 20 approach the digital mask 30. After the tray seat is fully pushed in, when the tray 20 is located at a higher end position on the other side of the inclining chute 221, the substrate 200 on the tray 20 is aligned with the digital mask 30.

In this embodiment, by using the inclining chute 221, the positioning baffle 222, and the pushing-in operation of the tray seat, the substrate 200 can approach to the digital mask 30, and due to the function of the inclining chute 221, no relative friction is generated between the substrate 200 and the digital mask 30 during an aligning process of the substrate 200 with the digital mask 30.

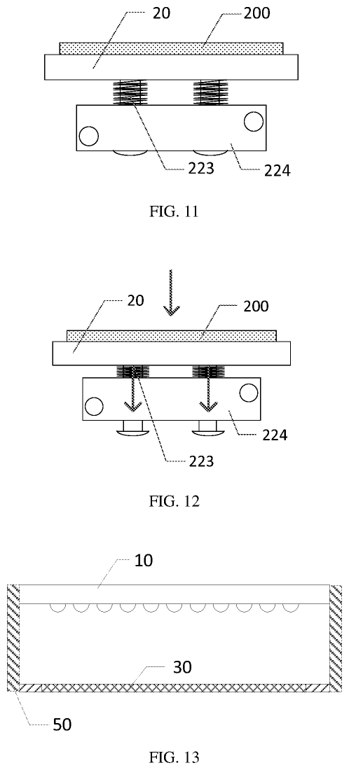

As shown in FIG. 11 to FIG. 12, in some embodiments, the approaching component 22 may further include: a spring mechanism 223 provided on the back of the tray 20 (an opposite side relative to the substrate). When the tray 20 is located in a higher-end position of the inclining chute 221, the spring mechanism 223 release its elasticity to push the tray 20 against the digital mask 30, so that the substrate 200 further approaches the digital mask 30. In some embodiments, the tray 20 is fixed on a bottom plate 224 by the spring mechanism 223. The bottom plate 224 slides into cooperation with the inclining chute 221 on the tray seat.

Furthermore, the positioning baffle 222 and the tray 20 may be provided with magnetic attraction components that cooperate with each other. The magnetic attraction components are configured to apply a driving force to the tray to move it to its lower end along the inclining chute 221. This embodiment is configured to enhance the effect of gravity, so that the tray can actively approach the inclining chute 221 as much as possible during its sliding process.

In some embodiments, the light source 10 in embodiments of the present disclosure is suitable for light with any wavelength band. When a wavelength band harmful to human body is used, a light shield 50 can be provided between the light source 10 and the digital mask 30.

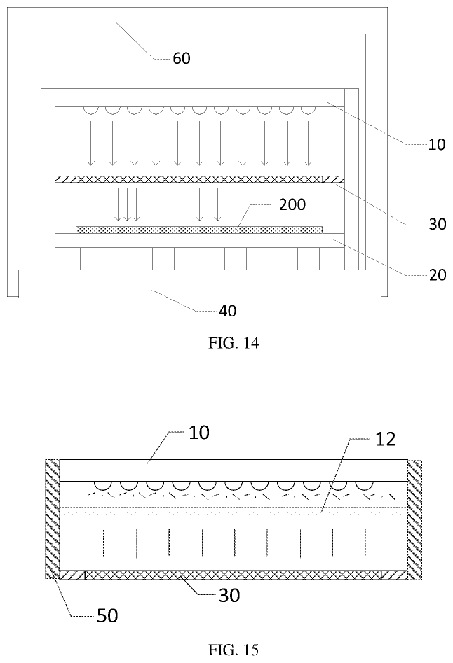

As shown in FIG. 13, in some embodiments, the light source 10, the light shield 50 and the digital mask 30 form a sealed cavity. Only when the light source and the digital mask work together, the light source emits light with consistent pattern from the digital mask of the sealed cavity. In this embodiment, the light source and the digital mask can be arranged at opposite sides of the light shield, for example, the light source 10 is arranged on the top of the light shield 50 and irradiates downward, and the digital mask is arranged on the bottom of the light shield opposite to the light source.

In some embodiments, the sealed cavity formed by the light source, the light shield and the digital mask is a vacuum structure to prevent impurities from affecting light propagation.

In some embodiments, when the light source selects a wavelength band not harmful to the human body, the above-mentioned light shield may also be provided, so as to achieve a sealed photocuring environment and avoid the influence of external light.

In some embodiments, for photo curing, the light source generally adopts a light source component with a light wavelength of 350 nm to 460 nm, e.g., ultraviolet light of 365 nm, ultraviolet light of 395 nm, blue violet light of 405 nm, and the like. The light source in embodiments of the present disclosure may be selected according to the specific photosensitive material (e.g., photosensitive resin material). In some embodiments, a light source capable of emitting multiple wavelengths can also be selected to cooperate a light blocking plate that blocks/transmits different light to obtain light of the target wavelength.

As shown in FIG. 14, in some embodiments, the photocuring device 100 further includes: a housing 60. The housing 60 can cooperate with the base 40 to accommodate components/modules such as the light source 10, the tray 20, and the digital mask 30. The housing can be a fully sealed housing or a semi-sealed housing, so as to achieve the overall or partial shielding/packaging of the device. For the fully sealed housing structure, it can be achieved by a combined structure. In some cases, the user can open the combined structure to replace/adjust the substrate, components, etc. After the operation is completed, the housing is combined to seal. In some embodiments, the housing 60 and the base 40 may be formed as an integral structure.

In some embodiments, the photocuring device further includes a control module. The control module is connected to the electronic function modules (e.g., digital mask, light source, etc.) of the photocuring device, so as to achieve the systematic control of various electronic function modules. The control module may be an integrated circuit board, a controller, a processor, etc., which can be directly purchased on the market.

In some embodiments, the photocuring device may further include a display component. The display component may be configured to display electronic graphic data of the digital mask and various operating parameter information of the photocuring device. The display component is connected to the control module.

In some embodiments, the photocuring device may further include a button component. The button component can satisfy independent control of the photocuring device, and includes, but not limited to, device switch buttons, data switching keys, power adjustment keys, and the like. The button component is connected to the control module.

In some embodiments, all/part of the functions of the display component and the button component can be controlled and displayed by using a touch screen.

In some embodiments, the photocuring device may further include: a data interface component. The data interface component can be used to connect to an external terminal device to implement systematic control of the photocuring device by the external terminal device. Alternatively, the data interface component is directly connected to an external storage device to obtain electronic graphic data used by the digital mask in the storage device. The data interface component is connected to the control module.

In some embodiments, the photocuring device further includes a necessary power supply module, which will not be elaborated here.

In some embodiments, the photocuring device may further include a heat dissipation component to dissipate the heat of the photocuring device, ensuring continuous and stable operation of the photocuring device.

In some embodiments, the light source can adopt a matrix light-emitting component, which includes: a reflective back plate and a light-emitting element fixed on the reflective back plate. A side of the reflective back plate close to the light-emitting element has a metal emitting surface for concentrating light at a side of the light-emitting element. In some embodiments, the heat dissipation component is mounted on the other side of the reflective back plate away from the light-emitting element, so as to take away the heat generated by the light source.

As shown in FIG. 15, in some embodiments, an optical lens 12 is provided between the light source 10 and the digital mask 30 to convert divergent light emitted by the light source 10 into uniform light in direction perpendicular to the digital mask 30. The optical lens 12 can be made of plastic, quartz glass and other materials.

The above-mentioned embodiments in the present disclosure can be combined arbitrarily, and all solutions obtained are within the protection scope of the present disclosure.

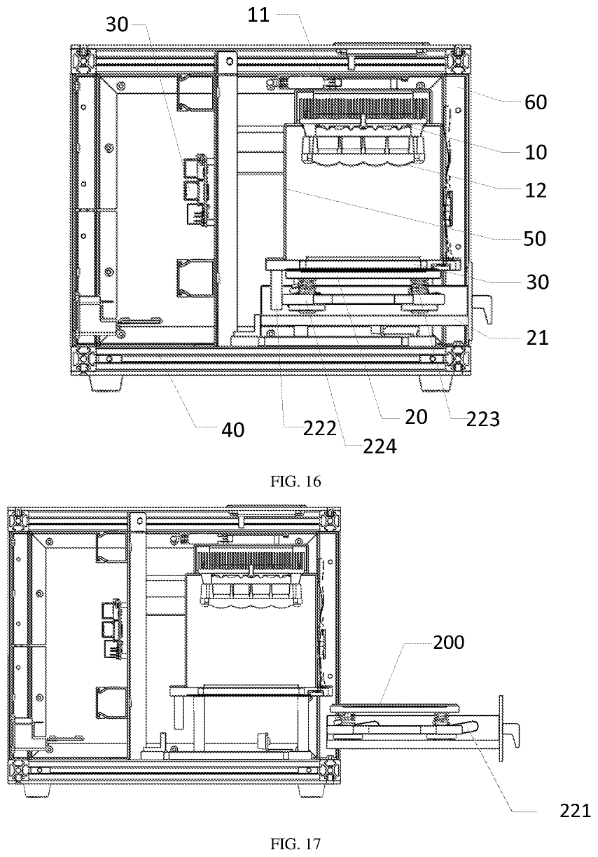

As shown in FIG. 16 to FIG. 17, the present disclosure further provides a photocuring device. The photocuring device includes: a base 40, a tray seat, an inclining chute 221, a positioning baffle 222, a digital mask 30, a light source 10, a light shield 50. The tray seat is assembled on the base 40 through a slide rail. The inclining chute 221 is provided on the tray seat. The tray 20 is assembled on the tray seat through the inclining chute 221. The positioning baffle 222 is provided on a moving path of the tray 20 to cooperate with the inclining chute 221 to position the tray 20 at a target position (a position relative to the digital mask 30 in a horizontal direction with a target distance in a vertical direction). The digital mask 30 is mounted right above the target position. The light source 10 is mounted right above the digital mask 30. A light shield 50 is provided between the light source 10 and the digital mask 30 and has an annular structure. The light source 10, the digital mask 30 and the light shield 50 collectively form a sealed cavity. An optical lens 12 is provided between the light source 10 and the digital mask 30 in the sealed cavity. A heat dissipation component 11 is provided outside the light source 10. The photocuring device 100 further includes: a housing 60. The housing 60 cooperates with the base 40 to shield internal components. A feeding port is provided in the housing 60 in a sliding direction relative to the tray seat. The feeding port is configured to push in and pull out the tray seat. A baffle plate is provided an outer side of the tray seat corresponding to the shape of the feeding port. The baffle plate is configured to cooperate with the housing 60 to form a sealed cavity structure (similar to a drawer) after the tray seat is pushed in. The outer side of the housing 60 is further provided with a power interface, a data interface component, a display component, a button component, etc. A control module 70 is provided inside the housing 60. The control module 70 is connected to the power interface, data interface component, the display component, the button component, the light source 10 and the digital mask 30.

In some embodiments, a compression spring is provided at the bottom of the tray 20 to release elasticity when the tray 20 moves to the higher end of the inclining chute 221, so that the tray 20 is pushed to approach the digital mask 30.

The photocuring device according to the present disclosure is suitable for a photo patterning curing device, and is especially suitable for realizing the photo curing process of the photosensitive material on the circuit board.

The substrate 200 in the present disclosure is suitable for a substrate in which a photosensitive dry film attached to its surface, or a substrate in which a pre-cured coating on its surface. The photosensitive material is not limited to solder resist, photosensitive resin, and the like.

Persons skilled in the art should understand that various illustrative logical blocks, modules, circuits, and algorithm steps described in connection with the embodiments herein may be implemented as electronic hardware, computer software, or combinations thereof. To clearly illustrate interchangeability between hardware and software, various illustrative components, blocks, modules, circuits, and steps have been described above generally in terms of their functionality. Whether this functionality is implemented as hardware or software depends on the specific application and design constraints imposed on the overall system. Persons skilled in the art may implement the described functionality in varying ways for each particular application, however, such implementation should not be interpreted as a departure from the scope of the present disclosure.

What is claimed is:

1. A photocuring device, comprising:
a base;
a light source fixed on the base;
a tray configured to place a substrate to be processed; and
a digital mask placed between the light source and the tray and configured to display a corresponding light-shielding pattern according to electronic graphics set by a user, so that light emitted by the light source passes through the digital mask to perform photocuring complementary to the light-shielding pattern for the substrate placed on the tray.

2. The photocuring device according to claim 1, wherein a distance between the light source and the digital mask is in a range from 10 mm to 500 mm.

3. The photocuring device according to claim 1, wherein a distance between the digital mask and the substrate is in a range from 0 mm to 30 mm.

4. The photocuring device according to claim 1, further comprising a light shield provided between the light source and the digital mask to prevent light leakage.

5. The photocuring device according to claim 1, further comprising a housing, wherein the housing covers the light source, the tray, and the digital mask.

6. The photocuring device according to claim 1, further comprising a moving component assembled on the base, wherein the tray is provided on the moving component so that the tray is capable of being drawn out by the moving component to place the substrate or take out the substrate, and the tray is capable of being pushed in by the moving component to align the substrate with the digital mask.

7. The photocuring device according to claim 6, wherein the moving component is a tray seat for fixing the tray, and the tray seat is mounted on the base through a slide rail.

8. The photocuring device according to claim 6, further comprising an approaching component cooperating with the tray, wherein the approaching component is configured to drive the substrate to approach the digital mask when the tray is pushed in, and drive the substrate to move away from the digital mask when the tray is being drawn out.

9. The photocuring device according to claim 1, wherein the digital mask is a digitally controlled light-shielding and light-transmitting display panel.

10. The photocuring device according to claim 9, wherein each of pixel points on the digitally controlled light-shielding and light-transmitting display panel is capable of forming a light-shielding pixel point or a light-transmitting pixel point according to the electronic graphics set by the user; the light-shielding pixel points constitute the light-shielding pattern, the light-transmitting pixel points constitute a light-transmitting pattern, and a pattern combined by the light-shielding pattern and the light-transmitting pattern is consistent with a pattern irradiated on the substrate by the light source.

11. The photocuring device according to claim 1, wherein the digital mask is selected from an LCD display panel or an OLED display panel.

12. The photocuring device according to claim 1, wherein light emitted by the light source has a wavelength of 350 nm to 460 nm.

13. The photocuring device according to claim 1, wherein an optical lens is provided between the light source and the digital mask and configured to convert a direction of the light emitted by the light source as a direction perpendicular to the digital mask.

14. The photocuring device according to claim 1, further comprising a heat dissipation component provided on a back plate of the light source.
